(19) United States
(12) Patent Application Publication
(10) Pub. No.: US 2022/0256466 A1
(43) Pub. Date: Aug. 11, 2022

(54) DEVICES AND METHODS FOR ADDING A POWER-SAVING SLEEP MODE TO PORTABLE ELECTRONIC DEVICES

(71) Applicant: OdinUP LLC, Zionsville, IN (US)

(72) Inventor: Daniel Langenberg, Zionsville, IN (US)

(73) Assignee: OdinUP LLC, Zionsville, IN (US)

(21) Appl. No.: 17/627,444

(22) PCT Filed: Jul. 16, 2020
(86) PCT No.: PCT/US20/42317

§ 371 Date: Jan. 14, 2022

Related U.S. Application Data
(60) Provisional application No. 62/875,450, filed on Jul. 17, 2019.

(51) Int. Cl. H04W 52/02; H05K 5/02

(52) U.S. Cl. CPC H04W 52/0251; H05K 5/0217

(57) ABSTRACT

Methods, systems, and devices are disclosed herein for incorporating a power-saving sleep mode into electronic devices using an activity-based switch device. These switch devices may have with a communication module having more advanced electronics, such as wireless communications features. These switch devices may be built into electronic devices and/or batteries during manufacture, and/or may also be retrofitted into already existing electronic devices and/or batteries. A switch device may be placed between a power source, such as a battery, and the electronic device. When activity or motion is detected, the switch closes to connect the power source to the electronic device, thus turning the portable electronic device “on” as normal. However, when activity is not detected for a meaningful amount of time, the switch opens and disconnects power from the electronic device to conserve power, thus placing the portable electronic device into a power-saving sleep mode to conserve the power source.

### PRIORITY

The present application is related to, and claims the priority benefit of, U.S. provisional Patent Application Ser. No. 62/875,450, filed Jul. 17, 2019, the contents of which are incorporated herein directly and by reference in their entirety

### BACKGROUND

Most portable electronic devices require battery power (or other energy storage) to operate. These portable electronic devices also contain and require a power switch to turn the device on or off. Some simple portable electronic devices, such as flashlights, consist of only a battery, a bulb, and a switch. These simple portable electronic devices are inexpensive, easy to manufacture, and work well when they have power from an energy storage device, such as a battery. However, upgrading these devices is difficult, unless you buy a new device.

While the simplicity of these portable electronic devices reduces the overall cost of the device, it can also create problems. For example, if a user forgets to turn off the portable electronic device for an extended period of time, the batteries are fully consumed and the device no longer works until the batteries are replaced. These simple, low-cost, portable electronic devices also sacrifice the attractive features of higher-end devices, such as the ability to remotely configure the power consumption levels, and/or enter a low-power or power-saving sleep mode when not in use. Thus, it would be desirable to incorporate an inexpensive, low-power, or power-saving sleep mode and/or a communication system into simple portable electronic devices and/or into the batteries themselves to save battery power. It would further be desirable for manufacturers to have a method for incorporating this low-power or power-saving sleep mode and/or communication system into the existing componentry within simple portable electronic devices, such as by implementing an activity-based smart switch between the batteries and the device.

More sophisticated portable electronic devices, such as cell phones or remote controls, include the ability to put the device into a low-power or power-saving sleep mode based on usage conditions. These devices will “wake up” when they detect motion, and may be set to enter a “low-power” mode state when they are not in use. Since these are more sophisticated electronic devices, they already include many of the support electronics required to create the more complete low-power or power-saving sleep modes. However, because the lower-cost portable electronic devices lack the more sophisticated electronic componentry, a different solution is needed to incorporate a low-power or power-saving sleep mode into these lower cost portable electronic devices.

Many simple portable electronic devices use replaceable, disposable batteries, such as AA or AAA batteries. Many of these devices are simple systems that do not include advanced electronic features such as a battery management system, and they simply drain the battery as needed. That means a radio in receive mode, a status LED, a small motor, or a display screen, is always “on” and draining the battery even when the user has stopped interacting with the product. Adding a low-power or auto-power-off circuit or sleep mode could save or extend the battery life for these products.

In some cases, the simple electronic devices don't have a communication system that allows for remote monitoring, remote data access, or user configuration. In these situations, adding an RF communications module could transform any “dumb” alkaline device into a more modern “smart” device. Most manufacturers forego these advanced functions to save on the manufacturing cost of the device or, they don't have the expertise or time to implement this type of circuit in the device. Thus, there exists a need to implement advanced electronic features, such as an RF communication module, and/or an auto power-off feature, to upgrade these everyday electronic devices.

The advanced electronic systems and devices disclosed herein can be both: 1) easily incorporated into new portable electronic devices during manufacture; and 2) easily retrofitted into already existing portable electronic devices and/or batteries. The ability to retrofit a portable electronic device with a low-power, or power-saving sleep mode, will prevent wasted batteries, as well as preventing consumers from simply throwing away older existing portable electronic devices. Adding RF communications will allow the user to remotely monitor the battery life, remotely switch the device on and off, receive relevant notifications (low battery), and may provide many other “smart” features found in higher end electronic devices.

Additionally, the systems disclosed herein utilizing these advanced electronic features are different from existing embedded devices. Turning a device on or off based on motion is common when considering a fully integrated or sophisticated electrical system, since the computational power and complexity is shared among multiple components. This is normally fully integrated into larger electrical systems to reduce cost and complexity of a design. However, if these advanced electronic features are not designed into the device at the time of manufacture, a consumer could never upgrade the device with the more advanced electronic features, such as adding a sleep mode, auto power-off, or wireless control in the system.

The systems and devices herein focus on the state-of-the-art manufacturing processes that enable placing significant computation, sensing, communicating, and switching capabilities into a package small enough to fit inside a battery compartment. This is a more expensive process than embedding it into the device at manufacturing. However, it has the benefit of being retrofittable inside an existing portable electronic device, allowing a consumer to take previously owned equipment and install a sleep mode or a “smart” advanced electronic feature set into any portable electronic device that they own. This also has the benefit of reducing the design complexity of the original system, removing the need for electrical engineers and firmware engineers for this functionality.

The power saving systems and advanced electronic features disclosed herein can operate at low voltages, such as in a single battery cell, as well as in larger systems that contain multiple batteries in series. This flexibility will allow the user or consumer to use only a single device, even if their portable electronic device requires multiple batteries in series, such as 3 AA batteries.

### BRIEF SUMMARY OF THE INVENTION

The present disclosure includes disclosure of a switch device having a power-saving sleep mode for use within an electronic device, wherein the switch device monitors activity of the electronic device to enter the power-saving sleep mode when the electronic device is not in use, the switch device comprising: a connection to a power node of the electronic device; a connection to the power source of the electronic device; an electrically controlled switch, positioned between the power node of the electronic device and the power source of the electronic device, wherein the electrically controlled switch is independently operable; and an activity sensor in communication with the electrically controlled switch and operable to monitor activity of the electronic device and, when activity is detected, turn on the electrically controlled switch to connect the power node of the electronic device to the power source of the electronic device to provide power to the electronic device; and when activity is not detected, turn off the electrically controlled switch to disconnect the power node from the power source to disconnect power to the electronic device and enter the power-saving sleep mode.

The present disclosure includes disclosure of a switch device, wherein the power node is in series with at least one additional battery and wherein electrical current enters the at the one additional battery prior to entering the power source of the electronic device.

The present disclosure includes disclosure of a switch device, further comprising a communication module in communication with the electrically controlled switch, the communication module comprising wireless or RF communications systems operable to add advanced electronic features to the electronic device.

The present disclosure includes disclosure of a switch device, wherein the advanced electronic features comprise wireless communications with external devices to modify, monitor, or record operations of the electronic device.

The present disclosure includes disclosure of a switch device, further comprising a connection to a mechanical input of the electronic device and wherein the switch device is incorporated into the electronic device during manufacture thereof.

The present disclosure includes disclosure of a switch device, wherein the switch device is retrofitted into a battery compartment of an already manufactured electronic device.

The present disclosure includes disclosure of a switch device, wherein the switch device is sized to fit inside a battery compartment of the electronic device.

The present disclosure includes disclosure of a switch device, wherein the power source comprises at least one battery.

The present disclosure includes disclosure of a switch device, wherein the power source is saved or conserved when the switch device is in the power-saving sleep mode.

The present disclosure includes disclosure of a switch device, wherein the electrically controlled switch further comprises an isolation barrier positioned between the electronic device and the power source, with the electrically controlled switch connected across the isolation barrier and operable to turn the electronic device on or off.

The present disclosure includes disclosure of a switch device, further comprising a timer to determine how long the electrically controlled switch will be connected before re-entering the power-saving sleep mode.

The present disclosure includes disclosure of a switch device, wherein the timer further comprises a discrete resistor(s), capacitor(s) and switches, the timer configured to use voltage decay of the capacitor to act as the timer, re-charging the capacitor whenever activity is detected by the activity sensor.

The present disclosure includes disclosure of a switch device, wherein the timer further comprises a microcontroller with a clock or counter, driven by an oscillator, to monitor how long it has been since activity was detected by the activity sensor.

The present disclosure includes disclosure of a switch device, wherein the electrically controlled switch is integrated into the timer.

The present disclosure includes disclosure of a switch device, wherein the activity sensor comprises two separate conductive surfaces, wherein a first conductive surface is expected to move when the electronic device is moved, and wherein the activity sensor senses a change in impedance between the two separate conductive surfaces during activity.

The present disclosure includes disclosure of a switch device, wherein the activity sensor comprises any of a plurality of sensors that can detect motion based upon thresholds or conditions, including: an accelerometer, a gyrometer, a magnetometer, an inertial measurement device, RF detectors, air pressure sensors, temperature sensors, or any other sensor that can directly or indirectly detect motion or usage of the electronic device.

The present disclosure includes disclosure of a switch device, wherein the activity sensor is an integrated sensor having additional algorithms to output key event triggers.

The present disclosure includes disclosure of a switch device, wherein the electrically controlled switch is a voltage enabled switch, a MOS transistor, a current enabled switch, a bipolar junction transistor, TRIAC, or SCR.

The present disclosure includes disclosure of a switch device, sized for removable placement around the battery.

The present disclosure includes disclosure of a switch device, wherein the electrically controlled switch is built in to a mechanical switch within the electronic device.

The present disclosure includes disclosure of a switch device, wherein the electrically controlled switch is built in to a battery holder of the electronic device.

The present disclosure includes disclosure of a switch device, wherein the electrically controlled switch is built in to a wiring harness of the electronic device.

The present disclosure includes disclosure of a switch device, wherein the electrically controlled switch is built in to a housing used to hold a subsystem of the electronic device.

The present disclosure includes disclosure of a switch device, wherein the electrically controlled switch is built into a subsystem housing used to connect to a primary system of the electronic device.

The present disclosure includes disclosure of a switch device, configured for use in connection with a method for incorporating the switch device into an electronic device to place the electronic device into a power-saving sleep mode, the method comprising: connecting the switch device to a power node of the electronic device; connecting the switch device to a power source of the electronic device to create a stable voltage to power the switch device; configuring an electrically controlled switch positioned between the power node of the electronic device and the power source of the electronic device, and wherein the electrically controlled switch is independently operable; starting a timer to determine how long the electrically controlled switch will remain connected to the power source before re-entering the power-saving sleep mode; configuring an activity detector to monitor activity of the electronic device; determining if activity has been detected; wherein detection of activity prompts the electrically controlled switch to connect power to the power source to turn the electronic device on, and restart the timer and activity detector; and wherein no detection of activity after a predetermined period of time prompts the electrically controlled switch to disconnect power from the power source to enter the power-saving sleep mode when the electronic device is not in use to conserve the power source.

The present disclosure includes disclosure of a switch device for monitoring activity of an electronic device and sized for placement around a battery, the switch device comprising mechanical and electrical connections to both a positive terminal and a negative terminal of the battery, and operable to consume some energy from the battery and use the consumed energy to modify its electromagnetic environment, such that all energy from the battery passes through the switch device.

The present disclosure includes disclosure of a switch device, wherein the switch devices operates within a primary power path of the battery and monitors activity of the electronic device; wherein the switch device modifies the electromagnetic environment by disconnecting the battery from the electronic device to enter a power-saving sleep mode when no activity is detected, and by connecting the battery to the electronic device to power the electronic device when activity is detected.

The present disclosure includes disclosure of a switch device, wherein the switch device operates independently from any other switch in the battery or the electronic device.

The present disclosure includes disclosure of a switch device, further comprising an activity sensor comprising any of a plurality of sensors that can detect activity based upon thresholds or conditions, including: an accelerometer, a gyrometer, a magnetometer, an inertial measurement device, RF detectors, air pressure sensors, temperature sensors, current sensors, and voltage sensors.

The present disclosure includes disclosure of a switch device, wherein the activity sensor activates a timer that keeps the electronic device awake for a preset amount of time until the timer is reset by additional sensed activity.

The present disclosure includes disclosure of a switch device, wherein the switch is a voltage enabled switch, a MOS transistor, a current enabled switch, a bipolar junction transistor, TRIAC, or SCR.

The present disclosure includes disclosure of a switch device, further comprising a timer, wherein the timer is modified by an algorithm to monitor activity levels, adjusts ON time, adjust OFF time, and adjust sensitivity levels of the electronic device, based on recorded historical values.

The present disclosure includes disclosure of a switch device, wherein the modification of the electromagnetic environment is through a radio-frequency communication system.

The present disclosure includes disclosure of a method for incorporating a switch device into an electronic device to place the electronic device into a power-saving sleep mode, wherein the switch device monitors activity of the electronic device and disconnects power from a power source to enter the power-saving sleep mode when the electronic device is not in use, and connects power to the power source to turn the electronic device on when activity is detected, the method comprising: connecting the switch device to a power node of the electronic device; connecting the switch device to a power source of the electronic device to create a stable voltage to power the switch device; configuring an electrically controlled switch positioned between the power node of the electronic device and the power source of the electronic device, and wherein the electrically controlled switch is independently operable; starting a timer to determine how long the electrically controlled switch will remain connected to the power source before re-entering the power-saving sleep mode; configuring an activity detector to monitor activity of the electronic device; determining if activity has been detected; wherein detection of activity prompts the electrically controlled switch to connect power to the power source to turn the electronic device on, and restart the timer and activity detector; and wherein no detection of activity after a predetermined period of time prompts the electrically controlled switch to disconnect power from the power source to enter the power-saving sleep mode when the electronic device is not in use to conserve the power source.

The present disclosure includes disclosure of a method, further comprising configuring a communications module to communicate with the electrically controlled switch, the communications module comprising wireless or RF communications systems operable to add advanced electronic features to the electronic device.

The present disclosure includes disclosure of a method, wherein the advanced electronic features comprise wireless communications with external devices to modify, monitor, or record operations of the electronic device.

The present disclosure includes disclosure of a method, wherein the power node is in series with at least one additional battery and wherein electrical current enters the at the one additional battery prior to entering the power source of the electronic device.

### BRIEF DESCRIPTION OF THE DRAWINGS

The disclosed embodiments and other features, advantages, and disclosures contained herein, and the matter of attaining them, will become apparent and the present disclosure will be better understood by reference to the following description of various exemplary embodiments of the present disclosure taken in conjunction with the accompanying drawings, wherein:

FIG. 1 illustrates an exemplary simplified block diagram of a switch device;

FIG. 2 illustrates an exemplary simplified flow diagram of operation of a switch device;

FIGS. 3A-3G illustrate multiple exemplary methods for powering a portable electronic device using different power structures, and multiple places for inserting the advanced electronic system switch device therein;

FIG. 4 illustrates an exemplary 3D rendering of an advanced electronic system retrofitted inside a battery pack;

FIG. 5A illustrates an exemplary a 3D rendering of a narrow style advanced electronic system for streamlined retrofitting applications;

FIG. 5B illustrates an exemplary a 3D rendering of a flat style advanced electronic system for streamlined retrofitting applications;

FIG. 6 illustrates an exemplary advanced electronic system device mechanically integrated into a battery compartment of a portable electronic device during manufacture;

FIG. 7A illustrates an exemplary circuit diagram for a switch device;

FIG. 7B illustrates an exemplary circuit diagram for a voltage conditioner;

FIG. 7C illustrates an exemplary circuit diagram for an activity sensor circuit;

FIG. 7D illustrates an exemplary circuit diagram for and a timer, controller, and RF Communication circuit;

FIGS. 8A-8F illustrate multiple exemplary plot diagrams for detecting activity using a switch device;

FIG. 9 illustrates an exemplary 3D rendering of a physical switch having a built-in advanced electronic system;

FIG. 10 illustrates an exemplary 3D rendering of a typical AA battery having the advanced electronic system built in to the energy storage device;

FIG. 11 illustrates a simplified block diagram of a wireless communication module interacting with the switch device and the optional motion sensor hardware;

FIG. 12 illustrates the building blocks inside an advanced electronic system; and

FIG. 13 illustrates the communication flow between a user and the device.

As such, an overview of the features, functions and/or configurations of the components depicted in the various figures will now be presented. It should be appreciated that not all of the features of the components of the figures are necessarily described and some of these non-discussed features (as well as discussed features) are inherent from the figures themselves. Other non-discussed features may be inherent in component geometry and/or configuration. Furthermore, wherever feasible and convenient, like reference numerals are used in the figures and the description to refer to the same or like parts or steps. The figures are in a simplified form and not to precise scale.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

The present disclosure includes various systems, devices, and methods for incorporating an activity-based switch device, and/or advanced electronic systems having wireless communications features, into electronic devices and/or batteries. The activity-based switch device(s), and more advanced electronic systems, may both include a low-power or power-saving sleep mode to conserve battery life. These systems, devices, and methods may operate by using the power from a primary battery cell to power ancillary electronics, such as a RF communication system, and/or by connecting or disconnecting the battery power based upon the activity of an external user.

The low-power or power-saving sleep-modes disclosed herein may be incorporated though an activity-based switch device and/or through advanced electronic systems inserted between a power input (such as a battery) and a portable electronic device (such as a flashlight). In both embodiments, these power-saving modes may be either: 1) incorporated into portable electronic devices at the time of manufacture; or 2) may be retrofitted into existing portable electronic devices; or 3) may be incorporated into the batteries themselves. The various systems, devices, and methods for incorporating an activity-based switch device and/or more advanced electronic features/systems into portable electronic devices, or batteries, are not limited to the embodiments shown herein, as they may vary in look, size, shape, number, electrical componentry, and accessories based upon each customer's requirements and each device's requirements and existing circuitry.

It should be understood that the activity-based switch devices disclosed herein may also be generally referred to hereinafter as “switch device(s)” (which may optionally include embodiments having more advanced electronic features therein). In some embodiments, the switch device(s) disclosed herein may mount in series with a separate system, switch, or power system, and can connect or disconnect from a battery power source based on the activity of an external user, such as based upon motion, for example. In one embodiment, switch device(s) may be small enough to fit inside the battery compartment of a portable electronic device without impeding the normal electrical circuit or battery operation.

In some embodiments, the switch device(s) may include an activity sensor, such as a motion detector, current sensor, or environmental sensor. When the sensor detects activity, such as the motion of a user picking up the portable electronic device, it allows battery power to flow through the system to operate or power the portable electronic device. When the sensor detects that it is no longer in use, the switch device(s) disconnects the battery power from the system, cutting off the continuity and forcing the portable electronic device into a low-power mode.

In an alternative embodiment, the switch device(s) may fit inside a battery, allowing the user to transfer the switch device between different portable electronic products that they might own. In yet another embodiment, the switch device may be attached to the battery, allowing a consumer to simply transfer the switch device between different batteries. In yet another embodiment, the switch device may be configured with more advanced electronic features, such as wirelessly using a low power communications technology. In yet another embodiment, the switch device may be activated directly through a low power communication technology without the need for user interaction.

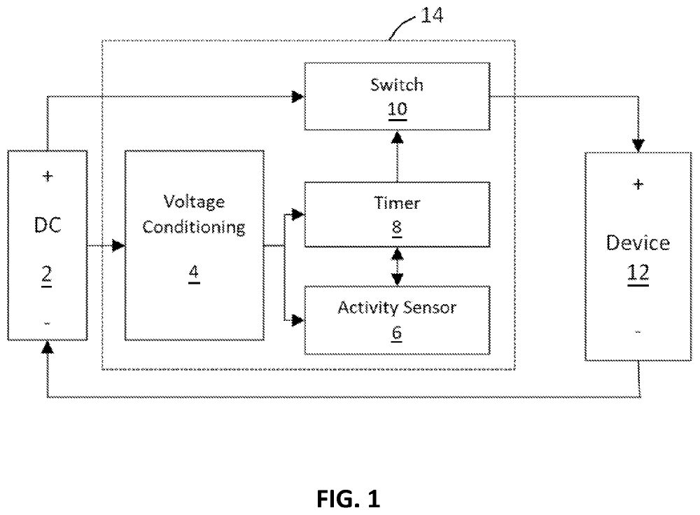

FIG. 1 illustrates an exemplary embodiment of a switch device 14, inserted between a power input 2, such as a battery, and a portable electronic device 12. The switch device 14 contains an input voltage conditioning circuit 4 that protects the switch device 14 components and provides a voltage node that can power the internal componentry. This conditioning circuit 4 may be any one of multiple topologies, including, but not limited to, buck converters, boost converters, linear regulators, RC regulators, Zener regulators, SEPIC converters, buck-boost converters, and any other method for creating a stable voltage node to power the internal componentry. A node is defined herein as a connection point between components in a circuit such as a wire to a battery, or the copper between components, while a “rail” is defined herein as a combination of nodes.

As shown in FIG. 1, the switch device 14 may also contain an activity sensor 6 that can be one of many different types of activity sensors. In one embodiment, the activity sensor 6 may be an accelerometer, which can be used to turn the electrical system (of a portable electrical device) on or off based upon motion. In other embodiments, the activity sensor 6 may be a motion detector, current sensor, or environmental sensor.

With continuing reference to FIG. 1, the switch device 14 may also contain a timer 8, such as a microcontroller, which controls the switch 10. When the activity sensor 6 detects activity, it turns on the timer 8, which then turns on the switch 10. The switch 10 may consist of an isolation barrier that separates the power input 2 from the portable electronic device 12, as well as a mechanism to connect the two sides when presented with the appropriate signal from the timer circuit 8. One embodiment may utilize a field-effect transistor (FET) to switch in and out the circuit. However, alternative embodiments could utilize a bipolar-junction transistor (BJT), an insulated-gate bipolar transistor, a relay, or any number of electrical or mechanical methods for switching a circuit.

The switch devices 14 disclosed herein are unique in that the activity sensor 6 (such as an accelerometer, for example) is not part of the design intent of the original system. Accelerometers typically require significant configuration, design, and testing to ensure they work appropriately in the different products. Accelerometers are also usually deeply integrated into the products, providing one or more functions for the primary system, including power management. However, this switch device 14 allows anyone to incorporate sophisticated power management (including an activity sensor 6, such as an accelerometer) into their portable electronic devices 12 without additional electrical design work. Additionally, this switch device 14 can simply be purchased by a general consumer and added to an existing portable electronic device 12 to add intelligent power features (such as a low-power or power-saving sleep mode) to their portable electronic device 12.

For example, multimeters have included low-power or power-saving sleep mode (or auto-power-off systems) for many years. Some multimeters include accelerometers to turn the device ‘on’ or ‘off’ based on motion. However, some manufacturers have removed the low-power or auto-off feature to reduce the cost of the final multimeter product. Without this switch device 14, an absent-minded engineer could purchase a multimeter that functions fine, but the batteries would need to be replaced on a regular basis. Currently, the engineer would either need to regularly replace the batteries, or they would have to throw away the multimeter and upgrade to a new multimeter with this function. Either option is a waste of money and a waste of perfectly good batteries or multimeters. By inserting this switch device 14 into an existing multimeter, the engineer can upgrade a working multimeter to an electronic device 12 with a low-power and/or auto-off feature, thus increasing the amount of time the electronic device 12 (i.e., multimeter) is usable, decreasing battery replacements, and keeping his functional multimeter. Thus, this switch device 14 can introduce valuable cost-saving features into an already existing portable electronic device 12.

The activity sensor 6 may be one or more sensors and may be a sensor that detects motion, a change of environment, or any change of usage (of portable electronic device 12 and/or batteries 2). The activity sensor 6 may comprise any combination, or a plurality of: an accelerometer (measuring acceleration of the device), a gyrometer (measuring the angular velocity of the device), a magnetometer (measuring the magnetic field around the device, including the earth's magnetic field), an inertial measurement device (using a single device that contains one or more motion sensors), RF detectors (measuring the changing RF magnet field around the device), air pressure sensors (measuring barometric pressure around the device), temperature sensors (detecting if a human is holding the device or not, or detecting change in the battery temperature, representing different activity uses), or any other sensor that can directly or indirectly detect motion or usage of the existing electronic device 12.

In one embodiment, the activity sensor 6 may monitor the change in power consumption of the portable electronic device 12. In another embodiment, instead of monitoring acceleration, it may monitor the change in air pressure that may represents a person lifting (i.e., picking up and/or using) the portable electronic device off of a table, for example. The activity sensor 6 may typically be looking for, or sensing motion, such as shaking, rotating, tapping, or otherwise moving the portable electronic device 12, and this motion must be larger than a pre-set threshold or a learned threshold to reconnect the battery and/or power input 2 to the portable electronic device 12.

If the activity sensor 6 does sense a pre-determined level of activity, it will reconnect the battery 2 (or power input) to the output terminal to provide power to the portable electronic device 12 (i.e., turn ‘on,’ resume power, or enter a “wake” mode). In some embodiments, an accelerometer may be used in a low-power alarm mode that will send a signal if the acceleration changes in a meaningful manner or by a predetermined amount/threshold. For example, a portable electronic device 12 sitting on a surface experiences 1 g (also known as a change in velocity of 9.8 m/s²) towards the earth. As long as the portable electronic device 12 continues to detect 1 g towards earth, it is not moving. If the accelerometer detects 1.1 g along any axis, then the electronic device 12 is moving. Similarly, detecting less than 1g towards earth would also mean the electronic device 12 is moving. Most modern accelerometers include “alarm” functions that will signal when any motion is detected, and that signal can be used to trigger the timer 8 and switch 10.

With continuing reference to FIG. 1, the timer 8 within the switch device 14 may be a microcontroller with a clock or counter driven by an oscillator to monitor how long it has been since the last activity event was detected. The timer 8 can be reset every time activity is detected (by the activity detector 6), acting as a “time out” alarm that will turn off the power output when the time expires. A less accurate method may involve charging up a capacitor when activity is detected, and using the discharge of the capacitor as a timing mechanism. This is typically seen in a “555 timer” based circuit, but can be as simple as a capacitor connected directly to the driver of the switch. Other embodiments may incorporate the timer 8 inside the motion sensor (i.e., activity sensor 6) itself

In one exemplary embodiment, the timer 8 may be a microcontroller which may also configure the activity sensor 6 based on pre-set values, thresholds, or based on a learning algorithm (or software program) which considers the average performance of the portable electronic device 12 over time, and adjusts the pre-set or threshold values accordingly. Additionally, some portable electronic devices 12, such as flashlights, may contain a simple timer 8. If motion is not detected for a pre-determined period of time (such as 10 seconds, for example) the power can be disconnected from the portable electronic device 12. However, more complex portable electronic devices 12, such as a model train, may require a learning algorithm to change the threshold (for disconnecting the power) based on historical data. This intelligent learning algorithm embodiment may provide a wider versatility of usage, even though the use cases may differ.

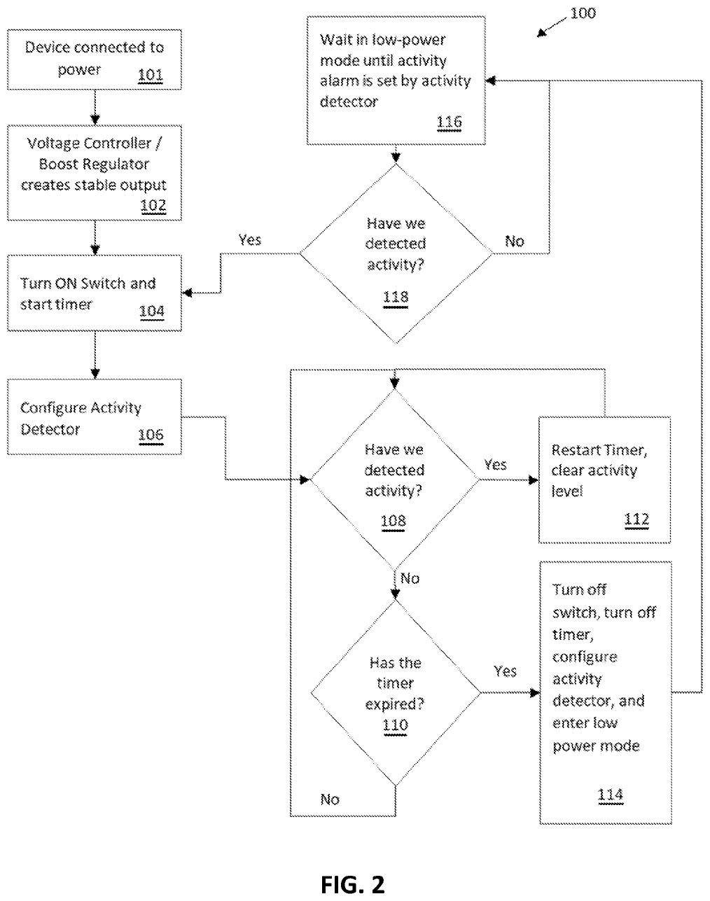

FIG. 2 illustrates a flow diagram of exemplary operation 100 of a circuit of a switch device 14. When the switch device 14 is first connected to power 101, the voltage converter (or boost regulator) 102 creates a stable output voltage to power the switch device 14. Upon the first power up, the electronic device 12 may turn on 104 the switch device 14 and starts the timer 8. This may provide a user or consumer with an opportunity to ensure that the electronic device 12 works properly without modification from the switch device 14. In this first power-up, the activity or motion sensor 6 may be configured 106 with “wake-up” activity threshold values, timeout values, and other configuration details. Next, the switch device 14 checks for activity 108 and checks to see if the timer 8 has expired 110. If activity is detected 112, the timer 8 may be reset and may or may not modify the activity threshold values (based upon the type of activity sensor 6 system being utilized).

In one exemplary embodiment, if the timer 8 has expired 110, then the switch device 14 may be turned off and the electronic device 12 enters the lowest power mode possible by turning off the timer and occasionally checking the activity levels. The electronic device 12 may then wait in a low-power mode 116 until activity is detected, at which point the electronic device 12 may turn on 104 the switch device 14, configure 106 the activity sensor, 6 and re-enter the main loop (starting at 108).

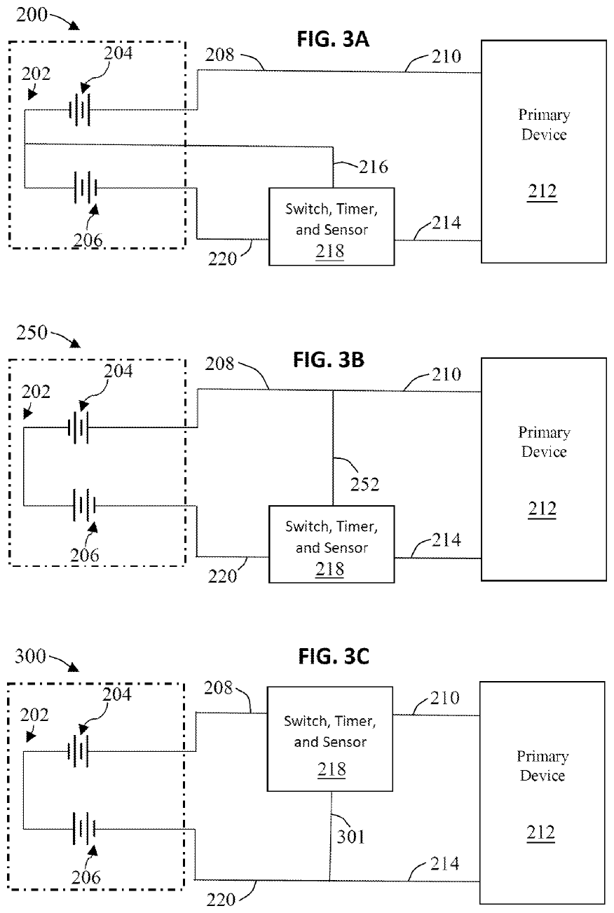

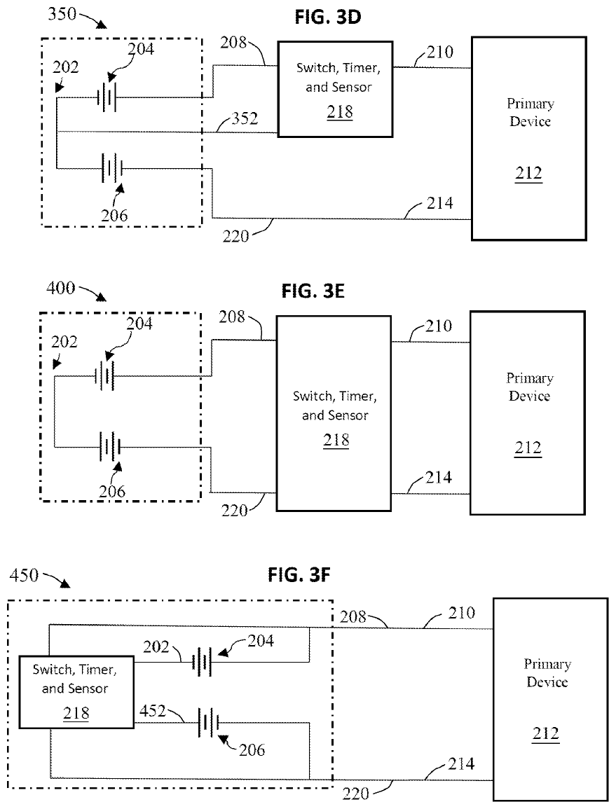

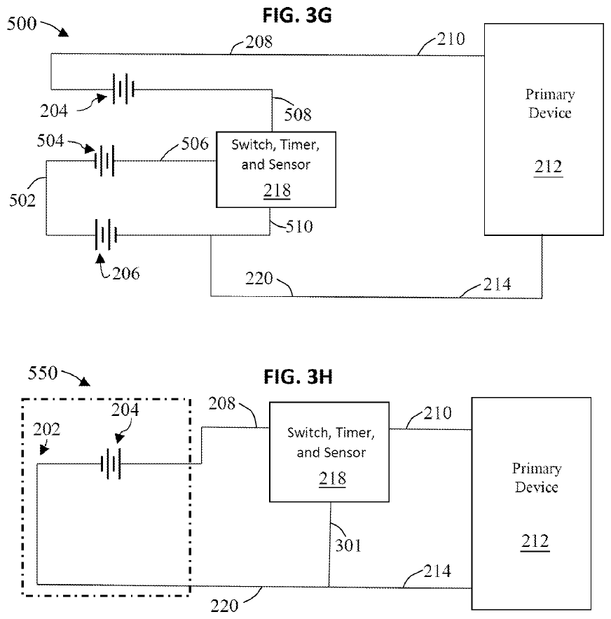

FIGS. 3A-3G illustrate multiple exemplary methods for powering a portable electronic device 12 using different power structures and switch topologies, and multiple locations for inserting the isolation barrier and switch device(s) 14 therein. These embodiments illustrate an exemplary symbol for a DC power source as 204, 206, and/or 504. In the following FIGS. 3A-3G, these exemplary power sources 204, 206, and/or 504 may represent one or more cells of a battery, with a range of voltages based on the battery chemistry and charge rates. Additionally, any reference herein to a negative terminal of a portable electronic device 12 may also be a positive terminal of another battery (such as in a series of batteries).

FIG. 3A illustrates an exemplary embodiment of a system 200 comprising two batteries 204 and 206 connected together 202, with battery outputs 208 and 220 going to a primary portable electronic device 212. In this embodiment, the switch device 218 may be inserted on the negative return wire between the primary portable electronic device output 214 and the battery input 220. A switch device 14 may be used to connect (or disconnect) the primary portable electronic device output 214 and the battery input 220 together based on the activity sensor and timer settings, as previous described above with reference to FIGS. 1 and 2. The switch device 14 may receive power from negative return wire which is connected to coupled batteries 202. This embodiment may be utilized when the sensor 6 is connected across a single power cell in a series battery system.

FIG. 3B illustrates an embodiment 250 of flexibility of the switch device 14 by connecting the power node of the switch device 14 directly to device input 210. This embodiment may be utilized when the sensor 6 is inserted in an already existing system, without easy access to a single cell system. For example, by using a connection 252, a P-channel MOSFET without any additional protection or drive circuit can be utilized. The use of a negative side connection, to interrupt 214 and 220, the voltage on connection 252 can be utilized to drive a P-channel MOSFET without any additional protection or drive circuit.

FIG. 3C illustrates an embodiment 300, having a high-side switch device 218, where the isolation barrier is between the battery output 208 and the device input 210. Additionally, a connection 301 may be added to the negative node to power the high-side switch device 218.

FIG. 3D illustrates an embodiment 350, having a high-side switch device 218, powered by a single battery cell, wherein the connection 352 provides power to the device 218 via the connection between the batteries 202. This embodiment may be utilized when placing a switch device 218 across a single battery.

FIG. 3E illustrates an embodiment 400, having a switch device 218 wherein the isolation barrier is placed across the positive and the negative rails (multiple nodes). This embodiment may be useful for topologies where the switch device 218 is to be inserted into an existing cable within a portable electronic device 12 or a larger system, but the user may not know which rail is the positive rail, and which rail is the negative rail.

FIG. 3F illustrates an embodiment 450, having a switch device 218 wherein the isolation barrier is connected between the batteries 202 and adds a connector 452. This embodiment may be useful for certain battery pack applications. Additionally, this embodiment may be powered using either 204 or 220, as previously described herein above.

FIG. 3G illustrates an embodiment 500, having a switch device 218 utilized inside a 3+ cell battery pack with a simple insert. Batteries 204, 206, and 504 may provide a higher series voltage than 1 or 2 cells. The switch device 218 may be inserted between battery 504 through wire 506, and into the switch device 218, with wire 508 connecting to battery 204. In this embodiment, the power return may be through wire 510.

FIG. 3H illustrates an embodiment 550, that is a duplicate of 3C, but uses only a single battery cell, having removed battery 206 and connecting 202 and 220 together.

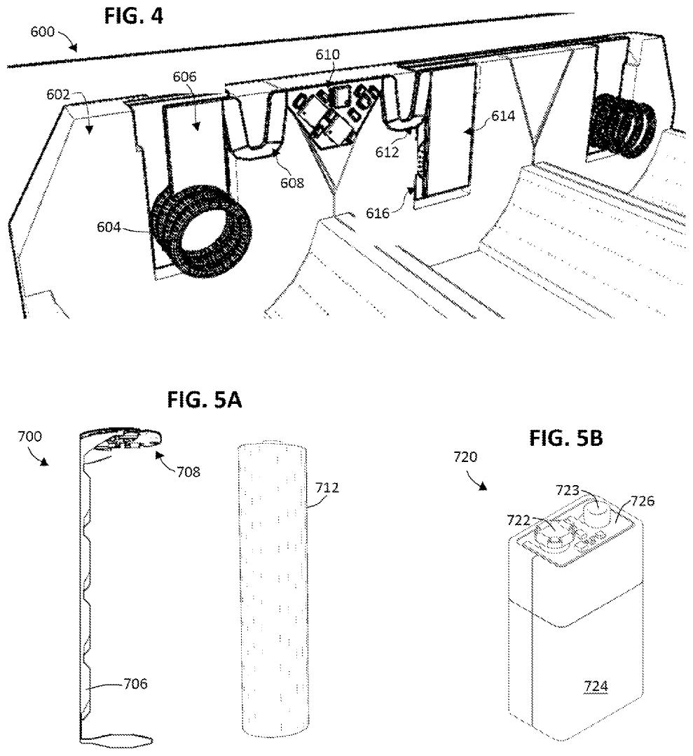

FIG. 4 illustrates an exemplary 3D rendering of a switch device 14 (shown as 610 in FIG. 4) retrofitted within a battery pack 600, as also described above in the embodiment 500 of FIG. 3G. (FIG. 4 further illustrates how the embodiment 500 of FIG. 3G would look in practice, since the circuit diagram of 3G may not be intuitive.) As shown in FIG. 4, the battery pack 600 may comprise multiple metal contacts housed inside a plastic housing 602. When compared to FIG. 3G above, 604 corresponds to wire 220, connector 616 corresponds to wire 506, and surface 614 provides both an isolation barrier, as well as a connection to battery 504.

As shown in FIG. 4, within the battery pack 600, there may be a built-in connector 616 corresponding to wire 508. On the other side of the battery pack 600, may be a similar topology used to make the series battery connections. The switch device itself is 610, with the components occupying the space between the batteries (within battery pack 600). Since battery packs 600 may have multiple internal plastic features for strength, a user might need to twist or move the circuit board to fit within the battery pack 600. Wire connectors 608 and 612 may be wires, or flexible PCB's, that allow twisting, flexing, or extending of the circuit board as required to fit inside the battery pack 600.

FIG. 5A illustrates an exemplary 3D rendering of a narrow style switch device 700 for streamlined retrofitting applications. This narrow style switch device 700 has a long, slim shape that may work well for flashlights, where a very thin connector 706 may be used to connect the negative terminal of the battery 712 to the negative terminal of the circuit within the switch device 700. An isolation barrier 708 may be disposed on the positive terminal of the thin connector 706, with the connection to the battery pack 712 connected through the switch device 700.

FIG. 5B illustrates an exemplary 3D rendering of an embodiment 720 of a 9-volt battery switch device for streamlined retrofitting applications. The 9-volt battery 724 coupled to switch device 726 may be a flat, thin shape for remote controls, portable RF transmitters, or other low power devices. In one embodiment, the circuit board contacts may clamp to the base of the battery terminals 722, 723, or may include a mechanical structure that fits on top of the 9v battery 724.

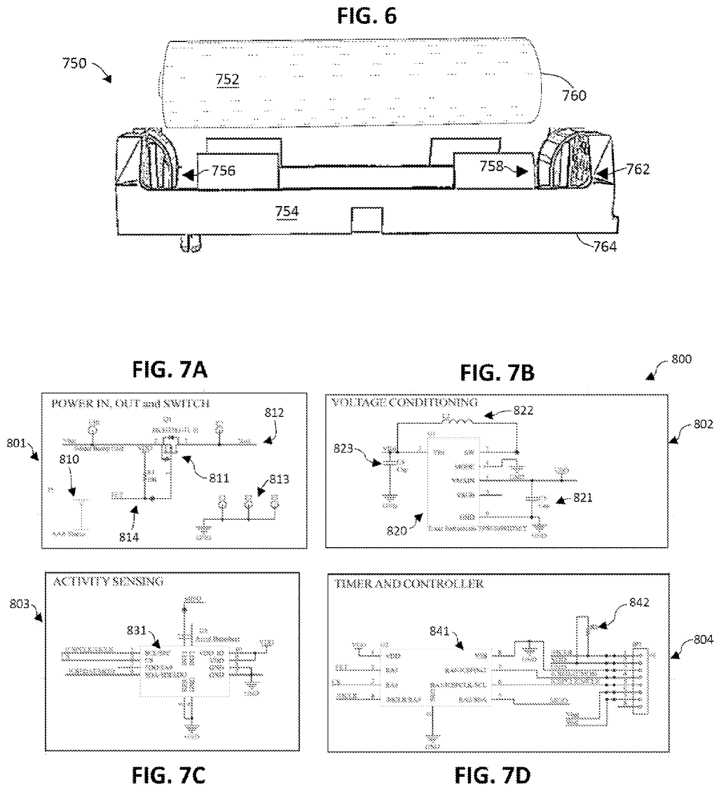

FIG. 6 illustrates an exemplary embodiment 750 of a switch device 762 mechanically integrated into a battery compartment 754 of a portable electronic device 12 (not shown in FIG. 6) during manufacture. In one embodiment, a switch device 762 may be inserted into a battery compartment 754 of a portable electronic device 12. This embodiment may be useful for manufacturers seeking a motion-activated power-saving auto-off unit without the work and expense of developing their own system. This embodiment may include a normal battery compartment (generally 754), with a positive terminal 756, a plastic body enclosure 754, and a negative terminal 758, all sized for receiving a standard sized battery 752. A switch device 762 having a circuit may be placed on the surface of the battery compartment 754, flat enough that it doesn't interfere with the battery negative terminal 760. The switch device 762 may also be placed on the outside surface of the battery compartment 754, or anywhere along the plastic battery compartment's 754 surface. The positive terminal 756 power may be routed along the surface or through the plastic battery compartment 754 itself to the switch device 762 (having the circuit 762), such as by using laser direct sintering, or other plastic-embedded wires. The negative battery connector 758 may connect to a portable electronic device through a connection point 764. The circuit within the switch device 762 may be connected between these nodes to provide the smart switch device capabilities (i.e., low-power or power-saving sleep modes).

FIGS. 7A-7D illustrate exemplary circuit diagrams 800 for: 1) a power in and out switch device 801; 2) a voltage conditioner 802; 3) an activity sensor circuit 803; and 4) a timer and controller circuit 804.

FIG. 7A illustrates an exemplary circuit diagram for an switch device 801 containing a two-terminal power input 810, a switch 811, such as a MOSFET, a connector to the external device 812, and a symbolic connection 814 to the external device 813. The switch device 801 may be any number of switches, including, but not limited to, a depletion-mode MOSFET, P-FET, J-FET, PNP transistors, SCRs, TRIACs, relays, or any other device that may change the amount of power flowing from the input 810 to the output 812. This embodiment illustrates a high-side example, however the switch device 801 may also change to the low-side 814, using N-channel enhancement or depletion mode MOSFET, P-FETs, J-FETs, NPN transistors, Darlington transistors, SCRs, TRIACs, or any other device that can change the amount of power flowing from the input 810 to the output 813. In this embodiment, 812 is the positive output terminal, and 813 is the negative output terminal.

FIG. 7B illustrates an exemplary circuit diagram for a voltage conditioner or switching regulator circuit 802. A switching regulator circuit 802 may be used where the switcher 820 uses an inductor 822 and capacitor 823 to provide a regulated output whose value is set by an external resistor 821. This particular circuit 802 may use a boost topology, but in practice there may be multiple different methods for providing a regulated output and this should be understood as being only one exemplary embodiment of many possible alternative embodiments. The voltage from the power may be anywhere between 0.8 v (for a single-cell battery) and 6 v system (where there are 4 cells in series) or more, and the microcontroller requires a stable voltage around 1.8 v to minimize battery power consumption.

FIG. 7C illustrates an exemplary circuit diagram for an activity sensor circuit 803. The activity sensor circuit 803 may have an accelerometer 831 and a decoupling capacitor.

FIG. 7D illustrates an exemplary circuit diagram for a timer and controller circuit 804. The timer and controller circuit 804 may comprise a microcontroller, a programming interface, and a programming interface resistor 842. These components may be included in the final design, or used purely in the manufacturing process.

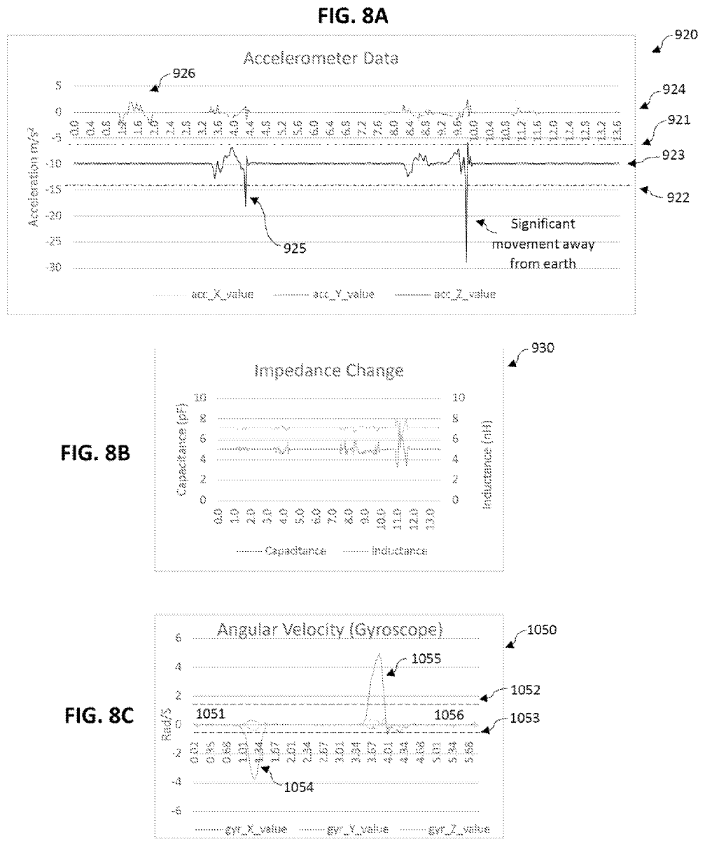

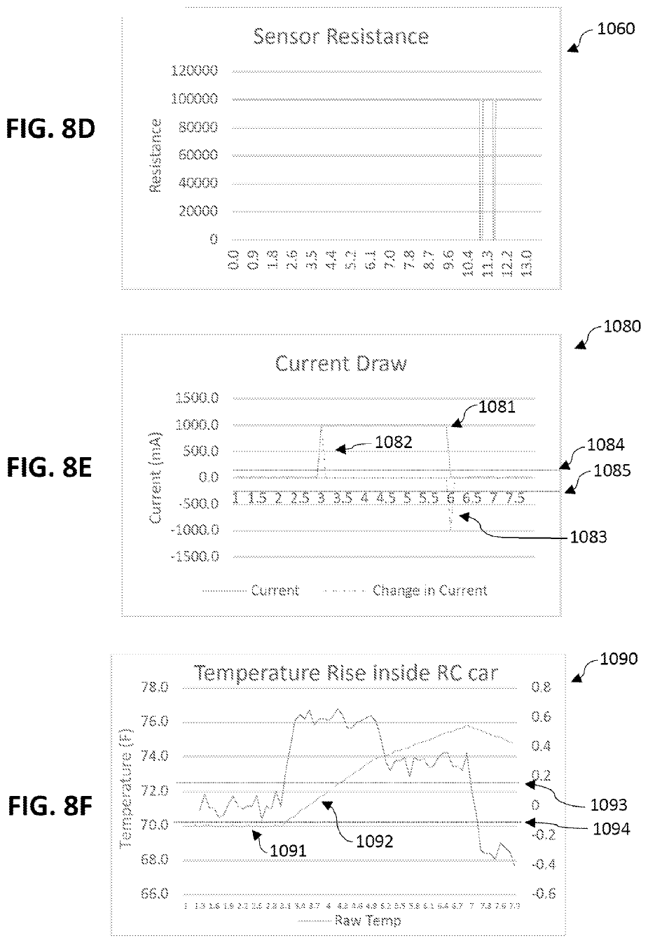

FIGS. 8A-8F illustrate multiple exemplary plot diagrams for detecting activity using an switch device 14.

FIG. 8A illustrates a plot 920 containing the output of a 3-axis accelerometer used to detect motion. When an electronic device 12 lies flat on a table or other surface, one axis points towards earth 923, providing a constant pull of −9.8 m/s². The other two axis 924 are stable around 0 because they don't have gravity pulling on them. Then, a threshold 921 and 922 may be programed in to set/determine an activity threshold level value, so that insignificant motion doesn't trigger the threshold, but significant motion 925 does trigger the threshold. The threshold level values can change based on learning or programmed algorithms, and the values themselves can be filtered with different methods to further improve accuracy and sensitivity, as desired. This information can then be plotted as a baseline to compare to other activity-based sensors, for example.

FIG. 8B illustrates a plot 930 utilizing impedance change (nH) v. capacitance (pF) to sense or detect activity. In this embodiment, if an accelerometer is simplified to its core function, it may measure the impedance of metallic surfaces and how they move when under a particular force. Generalizing this information, any measurement 930 of capacitance change or inductance change may then be used as an activity sensor 6, depending on the construction of the switch device 14.

FIG. 8C illustrates an exemplary plot 1050 of a gyroscope, measuring angular velocity, sensing or detecting activity. This embodiment may consume more power than an accelerometer, but may also be immune to gravity and the small vibrations one might see in some portable electronic devices 12, such as a model train for example. The plot 1050 also illustrates threshold values 1052 and 1053, as well as nominal values of no motion 105 and 1056, as well as higher motion moments 1054 and 1055 that may be utilized to trigger an activity detection.

FIG. 8D illustrates a plot 1060 utilizing metal surface contact to determine vibration, such as in a metal spring and rod system. This embodiment may measure resistance to sense or detect activity.

FIGS. 8E illustrates an exemplary plot 1080 of the ability of the switch device 14 to indirectly sense or detect activity. FIG. 8E illustrates power consumption, such as current draw (mA), where higher power consumption may mean turning a motor “on” corresponding to an increase in current 1081. This embodiment may compare a change in the current with the actual current being used to demonstrate that “something has changed,” thus the user may be utilizing the portable electronic device 12. The derivative information may be more informative than the steady-state signal, since the change in current 1082 and 1083 may be used with distinct threshold values 1084 and 1085 to determine or sense motion.

FIG. 8F illustrates an exemplary plot 1090 having temperature as an indirect measurement for sensing or detecting activity. In this embodiment, when the temperature of a battery 1091 is measured, it is likely around room temperature. However, when the portable electronic device 12 is turned on, or held in the hands of a user, there may be a rapid “rate of change” in the temperature 1092, indicating usage based on threshold values 1093 and 1094.

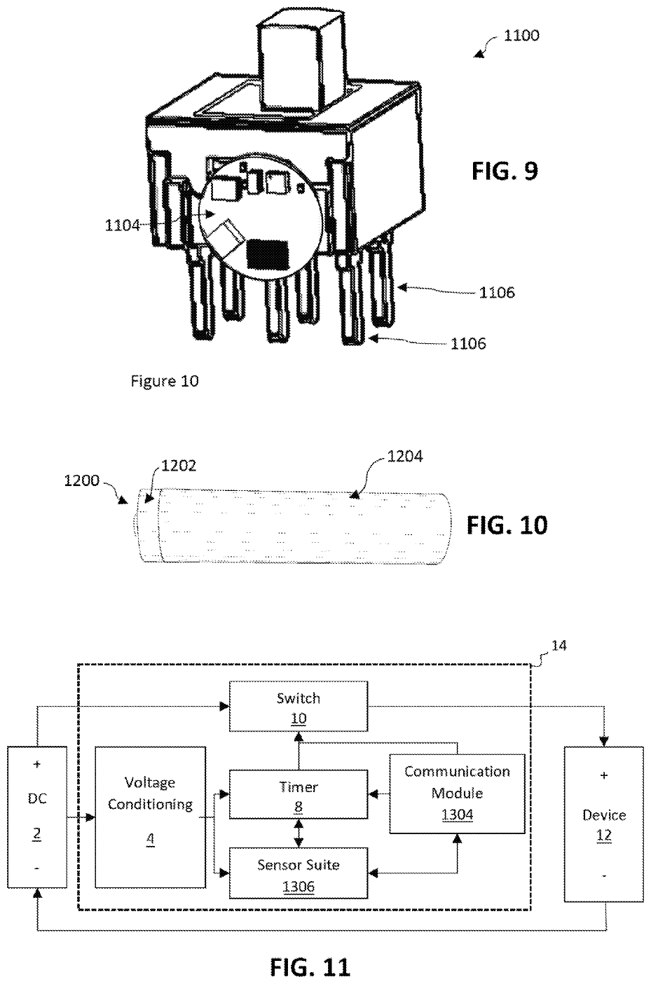

FIG. 9 illustrates an exemplary embodiment 1100 of a switch device 1104 mechanically integrated into a slide switch, as may be found inside some portable electronic devices 12, such as hand-held radios or other simple electronic devices 12. The switch device 1104 may connect to the legs of the switch 1106 in a manner similar to that already shown in FIG. 3 above, allowing a manufacturer to replace a standard switch with a smart switch device 14.

FIG. 10 illustrates an exemplary embodiment 1200 wherein a switch device 1202 (such as shown in FIG. 1, for example) is built directly into an end of battery 1204. When the switch device 1202 is built directly into a battery 1204, it may be attached or incorporated via a shrink-wrap tubing around battery cell 1204, with the electronics located at the tip or base of the battery (shown as 1202), held in place by the shrink wrap tubing, as shown in FIG. 10.

FIG. 11 builds upon the embodiment of the switch device 14 shown in FIG. 1, by adding a communication module 1304 which may include more advanced electronic features. In some embodiments, the communication module 1304 may take the place of the activity sensor 6 and/or switch 10. The more advanced electronic features of the communication module 1304 may include hardware and firmware required to interface the switch device 14 with an external electronic device 12. An external electronic device 12 may be any electronic device 12, such as a cellular telephone, desktop computer, central controller, or other home assistant operable through one or more RF communication (i.e., wireless) technologies. The RF communication technologies may utilize RF frequencies in the range of 300 MHz to 5 GHz, as well as higher-frequency technologies such as Ultra-Wide-Band (3.1 GHz to 10.6 GHz).

As shown in FIG. 11, the communication module 1304 may be electrically coupled to, and interface directly with, the sensor suite 1306, the timer 8, and/or the switch 10, to turn the electronic device 12 on or off to reduce power consumption. The sensor suite 1306 may include a motion sensor, but may also include a multitude of other sensors, such as temperature, humidity, and other pre-set or threshold values. In one exemplary embodiment, the more advanced electronic features of the communication module 1304 may be included in a single silicon package, or they may be broken out in one or more silicon packages to reduce size, cost, or complexity.

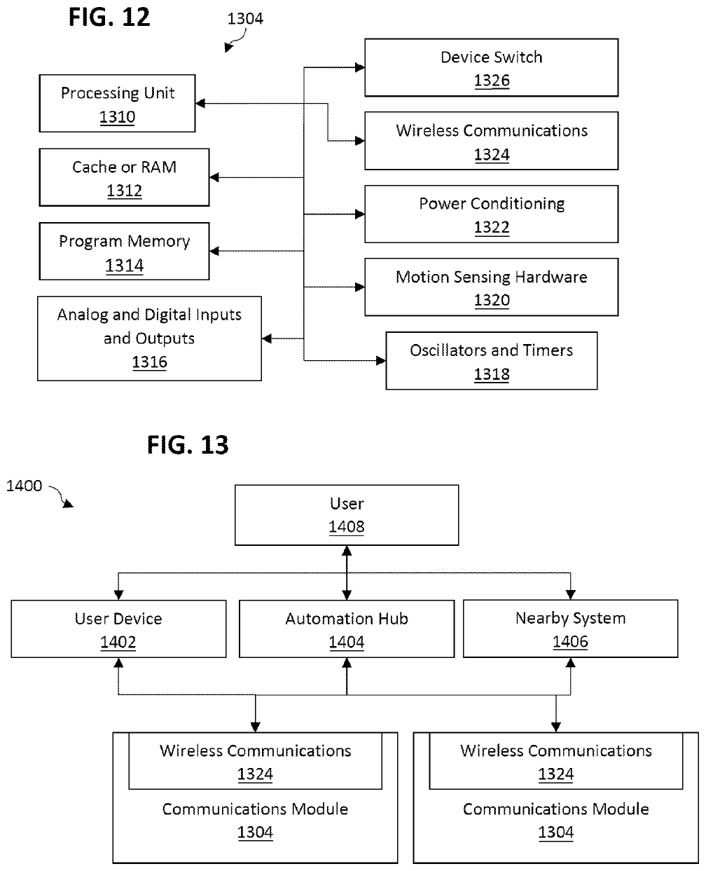

FIG. 12 outlines the advanced electronic system architecture of an exemplary communication module 1304. The communication module 1304 may include a processing unit 1310 which fetches instructions from the program memory 1314 and uses that information to interact with the cache or ram 1312, analog and digital inputs and outputs 1316, oscillators and timers 1318, motion sensing hardware 1320, power conditioning 1322, wireless communications 1324, and/or through the device switch 1326. One or more of these signals may travel over a unified bus 1304, or may have dedicated lines. In another embodiment, some designs may also place blocks outside of the RF architecture, and interface using the analog or digital inputs and outputs 1316.

FIG. 13 illustrates an exemplary communication path 1400 between the communication module 1304 (for adding advanced electronic system(s)) and the user 1408, such as via one of many wireless links, including a wireless communication protocol 1324 (Bluetooth or BLE, Zigbee, UHB, Wi-Fi, etc.) to a user device 1402, such as a cell phone, laptop, desktop computer, digital watch, or other device with a digital user interface. In some embodiments, communication module 1304 may communicate with user device 1402, and the user device 1402 may provide configuration data to communicate with the automation hub 1404. This automation hub 1404 may be a home assistant or other controller that provides some level of “automation” to the advanced electronic system of communication module 1304. Alternatively, the automation hub 1404 may be a wireless bridge (such as a router) or a gateway that translates the wireless signal from the communication module 1304 into a signal common or familiar to other devices in the network, such as a Bluetooth to Wi-Fi gateway. Automation hub(s) 1404 are typically seen in use with Wi-Fi and operate to bring a user device 1402 onto a secure wireless connection inside of a home or business.

In some embodiments, the user device 1402 and/or communications module 1304 may also communicate with another nearby system 1406. These systems can include a Wi-Fi network, BLE networks, or other wireless systems. In some topologies, one communication module may communicate to an adjacent communications module 1304, which then sends the signal to another user device 1402, and/or an automation hub 1404, and/or a nearby system 1406. This is typically called a Mesh network, or a repeater network. In these situations, the communication module 1304 may also communicate to nearby cellular or wide area networks 1406, like LORAWAN or other long-distance communication network. These are all different, yet similar, paths that lead to a user interaction into an application, web interface, or cell phone app, which allow the user to see the status of the user device 1402, modify the settings, and/or receive alerts about the status of the user device 1402.

While various embodiments of devices and systems and methods for using the same have been described in considerable detail herein, the embodiments are merely offered as non-limiting examples of the disclosure described herein. It will therefore be understood that various changes and modifications may be made, and equivalents may be substituted for elements thereof, without departing from the scope of the present disclosure. The present disclosure is not intended to be exhaustive or limiting with respect to the content thereof.

Further, in describing representative embodiments, the present disclosure may have presented a method and/or a process as a particular sequence of steps. However, to the extent that the method or process does not rely on the particular order of steps set forth therein, the method or process should not be limited to the particular sequence of steps described, as other sequences of steps may be possible. Therefore, the particular order of the steps disclosed herein should not be construed as limitations of the present disclosure. In addition, disclosure directed to a method and/or process should not be limited to the performance of their steps in the order written. Such sequences may be varied and still remain within the scope of the present disclosure.

1. A switch device having a power-saving sleep mode for use within an electronic device, wherein the switch device monitors activity of the electronic device to enter the power saving sleep mode when the electronic device is not in use, the switch device comprising:
a connection to a power node of the electronic device;
a connection to a power source of the electronic device, wherein the power source comprises at least one battery;
an electrically controlled switch, positioned between the power node of the electronic device and the power source of the electronic device, wherein the electrically controlled switch is independently operable; and. an activity sensor in communication with the electrically controlled switch and operable to monitor activity of the electronic device and, when activity is detected while the switch is in the power-saving sleep mode. turn on the electrically controlled switch to connect the power node of the electronic device to the power source of the electronic device to provide power to the electronic device; and when activity is not detected while the switch is turned on, turn off the electrically controlled switch to disconnect the power node from the power source to disconnect power to the electronic device and enter the power-saving sleep mode.

2. (canceled)

3. The switch device of claim 1, further comprising a communication module in communication with the electrically controlled switch, the communication module comprising wireless or RF communications systems operable to add advanced electronic features to the electronic device, wherein the advanced electronic features comprise wireless communications with external devices to modify, monitor, or record operations of the electronic device.

4. (canceled)

5. The switch device of claim 1, further comprising a connection to a mechanical input of the electronic device and wherein the switch device is incorporated into the electronic device during manufacture thereof.

6. The switch device of claim 1, wherein the switch device is retrofitted into a battery compartment of an already manufactured electronic device.

7. The switch device of claim 1, wherein the swi device is sized to fit inside a battery compartment of the electronic device

8-9. (canceled)

110. The switch device of claim 1, wherein the electrically controlled switch further comprises an isolation barrier positioned between the electronic device and the power source, with the electrically controlled switch connected across the isolation barrier and operable to turn the electronic device on or off

11. The switch device of claim 1, further comprising a timer to determine how long the electrically controlled switch will be connected before re-entering the power-saving sleep mode.

12-14. (canceled)

15. The switch device of claim 1, wherein the activity sensor comprises two separate conductive surfaces, wherein a first conductive surface is expected to move when the electronic device is moved, and wherein the activity sensor senses a change in impedance between the two separate conductive surfaces during activity.

16. The switch device of claim 1, wherein the activity sensor comprises any of a plurality of sensors that can detect motion based upon thresholds or conditions, including: an accelerometer, a gyrometer, a magnetometer, an inertial measurement device, RF detectors, air pressure sensors, temperature sensors, or any other sensor that can directly or indirectly detect motion or usage of the electronic device.

17. The switch device of claim 1, wherein the activity sensor is an integrated sensor having additional algorithms to output key event triggers.

18. (canceled)

19. The switch device of claim 1, sized for removable placement around the battery.

20.-25. (canceled)

26. A switch device for monitoring activity of an electronic device and sized for placement around a battery, the switch device comprising mechanical and electrical connections to both a positive terminal and a negative terminal of the battery, and operable to consume some energy from the battery and use the consumed energy to modify its electromagnetic environment, such that all energy from the battery passes through the switch device;
wherein the switch devices operates within a primary power path of the battery and monitors activity of the electronic device; wherein the switch device modifies the electromagnetic environment by disconnecting the battery from the electronic device to enter a power-saving sleep mode when no activity is detected, and by connecting;the battery to the electronic device to power the electronic device when activity is detected.

27. (canceled)

28. The switch device of claim 26, wherein the switch device operates independently from any other switch in the battery or the electronic device.

29. The switch device of claim 26, further comprising an activity sensor comprising any of a plurality of sensors that can detect activity based upon thresholds or conditions, including: an accelerometer, a gyrometer, a magnetometer, an inertial measurement device, RF detectors, air pressure sensors, temperature sensors, current sensors, and voltage sensors.

30. The switch device of claim 29, wherein the activity sensor activates a timer that keeps the electronic device awake for a preset amount of time until the timer is reset by additional sensed activity.

31. (canceled)

32. The switch device of claim 26, further comprising a tinier, wherein the timer is modified by an algorithm to monitor activity levels, adjusts ON time, adjust OFF time, and adjust sensitivity levels of the electronic device, based on recorded historical values.

33. (canceled)

34. A method for incorporating a switch device into an electronic device to place the electronic device into a power-saving sleep mode, wherein the switch device monitors activity of the electronic device and disconnects power from a power source to enter the power-saving sleep mode when the electronic device is not in use, and connects power to the power source to turn the electronic device on when activity is detected, the method comprising:
connecting the switch device to a power node of the electronic device;
connecting the switch device to a power source of the electronic device to create a stable voltage to power the switch device;
configuring an electrically controlled switch positioned between the power node of the electronic device and the power source of the electronic device, and wherein the electrically controlled switch is independently operable;
starting a timer to determine how long the electrically controlled switch will remain connected to the power source before re-entering the power-saving sleep mode;
configuring an activity detector to monitor activity of the electronic device;
determining if activity has been detected;
wherein detection of activity prompts the electrically controlled switch to connect power to the power source to turn the electronic device on, and restart the timer and activity detector; and
wherein no detection of activity after a predetermined period of time prompts the electrically controlled switch to disconnect power from the power source to enter the power-saving sleep mode when the electronic device is not in use to conserve the power source.

35. The method of claim 34, further comprising configuring a communications module to communicate with the electrically controlled switch, the communications module comprising wireless or RF communications systems operable to add advanced electronic features to the electronic device.

36. The method of claim 35, wherein the advanced electronic features comprise wireless communications with external devices to modify, monitor, or record operations of the electronic device.

37. The method of claim 34, wherein the power node is in series with at least one battery and wherein electrical current enters the at least one battery prior to entering the power source of the electronic device.
